(19) United States
(12) Patent Application Publication
(10) Pub. No.: US 2006/0251897 A1
(43) Pub. Date: Nov. 9, 2006

(54) Growth of carbon nanotubes to join surfaces

(75) Inventors: Lawrence S. Pan, Los Gatos, CA (US); Gang Gu, Palo Alto, CA (US); Jim Protsenko, San Jose, CA (US)

Correspondence Address: CARR & FERRELL LLP, 2200 GENG ROAD, PALO ALTO, CA, 94303, US

(73) Assignee: Molecular Nanosystems, Inc.

(21) Appl. No.: 11/124,005

(22) Filed: May 6, 2005

(51) Int. Cl. H01L 29/08; H01L 29/94; B32B 9/00

(52) U.S. Cl. 428/408; 423/445 R; 257/368; 257/29

(57) ABSTRACT

Methods for joining two objects through the growth of carbon nanotubes from one or both of two opposing surfaces of the two objects, and interfaces formed between the two objects, are provided. Carbon nanotubes grown from both of the opposing surfaces can interdigitate to secure the two objects together. A metal layer can also be placed on one of the opposing surfaces such that carbon nanotubes growing from the other opposing surface bond with the metal layer. In addition to the mechanical bond, the carbon nanotubes can also provide thermal and electrical conductivity between the objects.

### STATEMENT REGARDING FEDERALLY SPONSORED RESEARCH OR DEVELOPMENT

This invention was made with United States Government support under Cooperative Agreement No. 70NANB2H3030 awarded by the Department of Commerce's National Institute of Standards and Technology. The United States has certain rights in the invention.

### BACKGROUND OF THE INVENTION

1. Field of the Invention

The present invention relates generally to the field of materials science and more particularly to forming structures that employ carbon nanotubes for thermal dissipation.

2. Description of the Prior Art

A carbon nanotube is a molecule composed of carbon atoms arranged in the shape of a cylinder. Carbon nanotubes are very narrow, on the order of nanometers in diameter, but can be produced with lengths on the order of microns. The unique structural, mechanical, and electrical properties of carbon nanotubes make them potentially useful in electrical, mechanical, and electromechanical devices. In particular, carbon nanotubes possess both high electrical and thermal conductivities in the direction of the longitudinal axis of the cylinder. For example, thermal conductivities of individual carbon nanotubes of 3000W/m° K and higher at room temperature have been reported.

The high thermal conductivity of carbon nanotubes makes them very attractive materials for use in applications involving heat dissipation. For example, in the semiconductor industry, devices that consume large amounts of power typically produce large amounts of heat. The heat must be efficiently dissipated to prevent these devices from overheating and failing. Presently, such devices are coupled to large heat sinks, often through the use of a heat spreader. Additionally, to allow for differences in coefficients of thermal expansion between the various components and to compensate for surface irregularities, thermal interface materials such as thermal greases are used between the heat spreader and both the device and the heat sink. However, thermal greases are both messy and require additional packaging, such as spring clips or mounting hardware, to keep the assembly together.

Therefore, what is needed are better methods for attaching heat sinks, sources, and spreaders that provides both mechanical bonding and improved thermal conductivity.

### SUMMARY

An exemplary method of the invention is directed to joining two objects such as a heat generation source and a thermal management aid. The method comprises a step of providing the two objects so that the objects have opposing surfaces kept apart by a distance, and a step of growing carbon nanotubes from a surface of one of the two objects until a mechanical bond is formed between the two objects. The surfaces can be kept apart, for example, by a spacer such as a bead. In some embodiments, one of the two objects includes a pedestal and the pedestal is used to keep the surfaces apart. The step of providing the two objects can include, in some embodiments, providing a clamping pressure to secure the two objects together while the carbon nanotubes are being grown to prevent the growing nanotubes from pushing the objects apart.

The step of growing the carbon nanotubes can include growing the carbon nanotubes from either or both of the two opposing surfaces. When the carbon nanotubes are grown from both surfaces, the step of growing the carbon nanotubes can include interdigitating the carbon nanotubes from the two surfaces.

In some embodiments, the step of growing the carbon nanotubes includes passing a process gas between the two opposing surfaces. The step of passing the process gas between the two opposing surfaces can include passing the process gas through a via in one object, in some of these embodiments. Additionally, one of the two opposing surfaces can include a catalyst layer, and in these embodiments growing the carbon nanotubes can include growing the carbon nanotubes from the catalyst layer. The step of growing the carbon nanotubes can further include growing generally aligned carbon nanotubes and growing carbon nanotubes with different properties from the opposing surfaces.

The method of the invention can further comprise a step of filling an interstitial space between the two objects with a matrix material after growing the carbon nanotubes. The matrix material surrounds the carbon nanotubes and adds further mechanical strength to the bond. Similarly, the method can further comprise a step of bonding the carbon nanotubes, growing from a surface of one of the two objects, to a metal layer disposed on a surface of the other of the two objects.

The present invention also provides embodiments directed to different interfaces. An exemplary interface between two objects having opposing surfaces comprises a first catalyst layer disposed on a first of the opposing surfaces and a second catalyst layer disposed on a second of the opposing surfaces, and generally aligned carbon nanotubes extending from each of the catalyst layers towards the other. The first and second catalyst layers can be either of the same or different compositions, and in some embodiments either catalyst layer can include a compositional gradient. Either catalyst layer can also include a pattern so that the carbon nanotubes extend from that layer according to the pattern.

The interface can further comprise a spacer between the opposing surfaces. The carbon nanotubes from the two surfaces are at least partially interdigitated in some of these embodiments. Moreover, the carbon nanotubes extending from the opposing surfaces can be characterized as having different defect levels. The interface can further comprise a matrix material disposed between the opposing surfaces and around the carbon nanotubes. In some embodiments, the interface further comprises carbon nanotubes extending essentially perpendicularly to the generally aligned carbon nanotubes extending from each of the catalyst layers, and together the carbon nanotubes comprise a 3-dimensional mesh between the opposing surfaces.

Another interface of the invention comprises a metal layer disposed on a first of the opposing surfaces, and generally aligned carbon nanotubes extending from a second of the opposing surfaces and bonded to the metal layer. In some embodiments the second of the opposing surfaces is a surface of a catalyst layer. Also, the metal of the metal layer can have a melting point in the range of about 600° C. to about 1000° C., in some instances.

Still another interface of the invention comprises a pedestal that is integral with a first of two objects having opposing surfaces separated by a distance. The pedestal extends across the distance to contact an opposing surface of a second of the two objects. The interface also comprises generally aligned carbon nanotubes extending from the opposing surface of the second object towards an opposing surface of the first object

### BRIEF DESCRIPTION OF DRAWINGS

FIGS. 1-3 show three successive cross-sections of two objects being joined together by carbon nanotubes according to an embodiment of the method of the invention.

FIG. 4 shows a top view of a surface of an object having a catalyst layer comprising a plurality of catalyst sites according to an embodiment of the invention.

FIG. 5 shows a top view of a surface of an object having a catalyst layer comprising a catalyst gradient according to an embodiment of the invention.

FIG. 6 shows a cross-sectional view of two objects being joined together according to an embodiment of the invention where vias in one object provide process gases to the space between the objects.

FIG. 7 shows a cross-sectional view of two objects being joined together according to an embodiment of the invention in which catalyst layers on opposing surfaces comprise different catalytic materials.

FIG. 8 shows a cross-sectional view of two objects being joined together according to an embodiment of the invention in which one object includes pedestals to maintain a spacing between the two objects.

FIG. 9 shows a cross-sectional view of two objects being joined together according to an embodiment of the invention in which carbon nanotubes grown from one object bond to a metal layer on a surface of the other object.

### DETAILED DESCRIPTION OF THE INVENTION

The present invention provides methods for joining two objects through the growth of carbon nanotubes from one or both of two opposing surfaces of the two objects. Where the carbon nanotubes are grown from both of the opposing surfaces, the carbon nanotubes can interdigitate to secure the two objects together. As used herein, “interdigitate” means to become intertwined, enmeshed, entangled, interlocked, or at a minimum, adhered together by Van der Waals forces. In some instances the interdigitated carbon nanotubes form a bond that is analogous to the bond formed by the hooks and loops of Velcro.

Besides providing a mechanical bond, the interdigitated carbon nanotubes can also provide excellent thermal and electrical conductivity between the objects. Additionally, the carbon nanotube growth can be patterned on either or both of the opposing surfaces. In some of these embodiments the carbon nanotubes can be grown to either partially interdigitate or not interdigitate, depending on the patterns on the surfaces and the alignment therebetween. Further, in some embodiments a metal layer can be placed on one of the opposing surfaces such that carbon nanotubes growing from the other opposing surface bond with the metal layer.

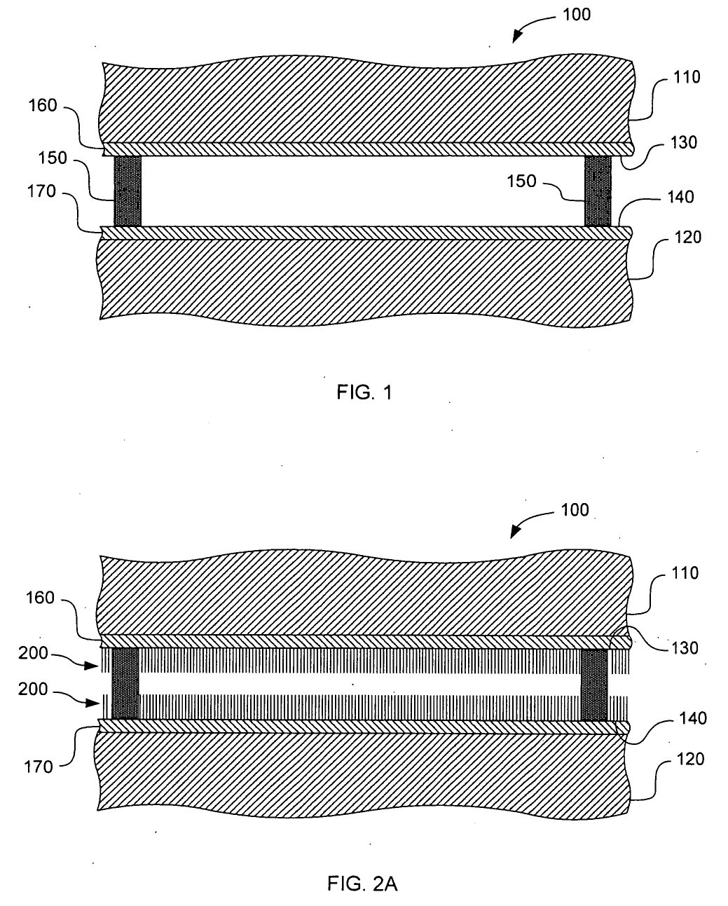

An exemplary embodiment of the method comprises the steps of providing two objects with opposing surfaces, and growing carbon nanotubes from both opposing surfaces until the carbon nanotubes are interdigitated. FIGS. 1-3 schematically illustrate this exemplary method of the invention at three successive points in time. FIG. 1 shows an assembly 100 comprising two objects 110 and 120 having opposing surfaces 130 and 140, respectively. Pressure can be applied by a clamp or weight, for instance, to secure the assembly 100 during subsequent steps. Examples of objects 110 and 120 include a heat generation source and a cooling aid.

The heat generation source can be anything that produces heat and requires cooling like a semiconductor die or a laser diode. Likewise, the cooling aid can be anything that draws heat away from the heat generation source such as a thermal management aid, heat spreader, heat sink, or cold plate. While the method of the invention is generally described herein with reference to assemblies for heat dissipation, due to the advantages provided by carbon nanotubes for such uses, it will be understood that the invention is not limited to these applications.

The two objects 110, 120 are kept apart by a fixed distance, in some embodiments, by one or more spacers 150. Alternately, a mechanical fixture can be used to maintain the desired fixed separation. The spacers 150 can be beads, small disks, or parallel rods, for example. It will be appreciated, however, that in order to get process gases between the two surfaces 130, 140 in subsequent steps, the spacers 150 are preferably kept as small as possible to not interfere with the flow of the process gases. Similarly, in those embodiments in which the spacers 150 do not contribute to the bonding of the objects 110, 120, the footprint of each spacer 150 on the objects 110, 120 is also preferably minimized.

The spacers 150 may ultimately become incorporated into the final structure, in some instances, while in other instances the spacers 150 are placed close to ends of the objects 110, 120 so that they can be readily removed at the completion of the method. In some embodiments the spacers 150 are made of a material, such as copper, that will not be corroded by the reactants nor promote the nucleation of either carbon nanotubes or other forms of carbon such as graphite. Other embodiments permit the carbon nanotubes to grow on the spacers 150, as discussed below.

One or both of the objects 110 and 120 can optionally include a thin catalyst layer 160 and 170, respectively. In some processes used to grow carbon nanotubes, described further below, such catalysts are useful to greatly increase the rate of carbon nanotube growth. In these embodiments, the surfaces of the catalyst layers 160, 170 become the surfaces 130, 140 upon which the carbon nanotubes are grown in subsequent steps. In some embodiments it is desirable to select different materials for the catalyst layers 160, 170, as also described in more detail below, in order to produce carbon nanotubes with different properties from the opposing surfaces 130, 140.

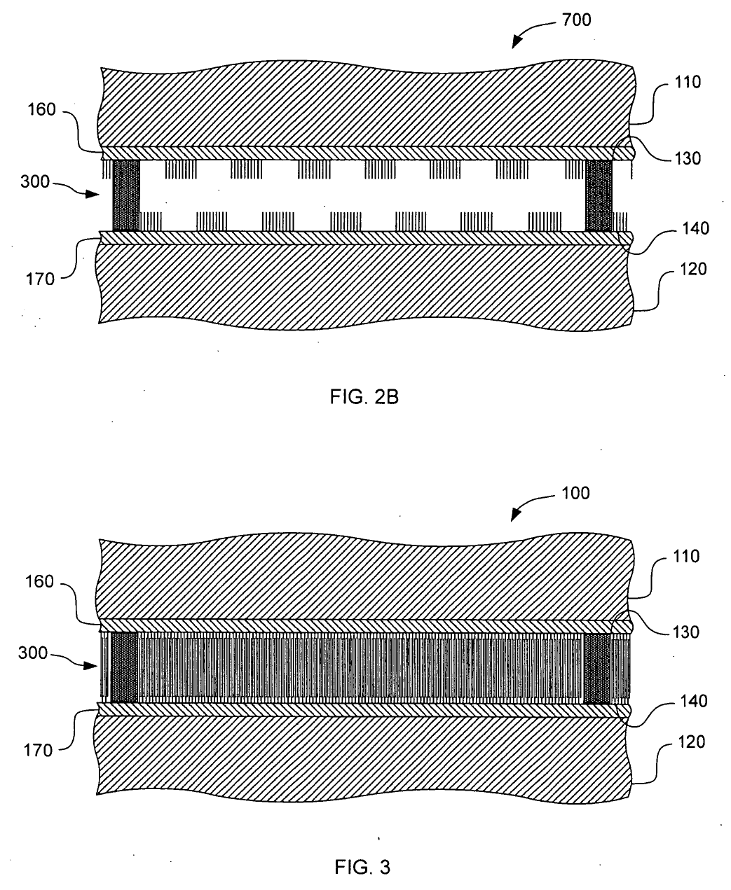

FIG. 2A illustrates carbon nanotubes 200 growing from the opposing surfaces 130, 140. It can be seen that the carbon nanotubes 200 are generally aligned with one another and grown in an orientation that is substantially perpendicular to the opposing surfaces 130, 140. Although the carbon nanotubes 200 in FIG. 2A are shown as growing at uniform rates from both surfaces 130, 140 and evenly across both surfaces 130, 140, it will be understood that the growth rate and physical properties of the carbon nanotubes 200, in some embodiments, can be varied both across and between surfaces 130, 140. Methods for achieving such varied growth will be described more fully below.

It is also noted that the spacers 150 (FIG. 1) can also be coated with a catalyst so that carbon nanotubes 200 grow horizontally from the spacers into the vertical network growing from the surfaces 130, 140 to create a 3-dimensional mesh. Such a configuration is suitable for a heat spreader since it readily transmits heat laterally as well as vertically.

Additionally, as shown in FIG. 2B, the catalyst layers 160, 170 can be patterned by conventional patterning techniques so that the carbon nanotubes 200 grow from the surfaces 130, 140 according to those patterns. When the patterns of the catalyst layers 160, 170 are aligned such that the patterns are negatives of one another, islands of carbon nanotubes 200 from each surface 130, 140 grow unimpeded towards the opposite surface 140, 130. The islands of carbon nanotubes 200 from opposite surfaces 130, 140 may or may not partially interdigitate around their peripheries, depending on the patterns and the growth conditions. In those embodiments where the patterns are not negatives of one another the patterns can be designed to provide varying degrees of either overlap or separation between the opposing islands.

One general method for achieving carbon nanotube growth between the surfaces 130, 140 is to heat the assembly 100 while flowing a carbon-bearing gas between the surfaces 130, 140. Catalyst layers 160, 170 can be beneficially employed. Examples of suitable catalysts and process conditions are taught, for example, by Erik T. Thostenson et al. in “Advances in the Science and Technology of Carbon Nanotubes and their Composites: a Review,” Composites Science and Technology 61 (2001) 1899-1912, and by Hongjie Dai in “Carbon Nanotubes: Opportunities and Challenges,” Surface Science 500 (2002) 218-241. It will be appreciated, however, that the present invention does not require preparing the carbon nanotubes by the catalysis methods of either of these references or U.S. patent application Ser. No. 10/943,321, and any method that can produce generally aligned carbon nanotubes extending from a surface is acceptable.

In contrast to the prior art processes for growing carbon nanotubes on substrates, it will be appreciated that implementing the present invention requires carbon nanotube growth to occur in a fairly narrow space which imposes special requirements in order to maintain adequate growth conditions between the surfaces 130, 140. For example, in order to provide process gases between the surfaces 130 and 140, the gases can be introduced under pressure through nozzles. The nozzles can be positioned close to the space between the surfaces 130, 140 and oriented to direct gases into the space from several different directions. Bellows or similar means can also be employed to constrain the flow of gases to within the space between the surfaces 130, 140. Other techniques that can be used to address the requirements of the narrowness of the space between the surfaces 130, 140 are discussed below.

FIG. 3 illustrates interdigited carbon nanotubes 300 grown from the opposing surfaces 130, 140. Once sufficiently interdigitated, the carbon nanotubes provide a mechanical bond that can also conduct heat and electricity. In some embodiments, the carbon nanotubes 300 grow until at least some of the carbon nanotubes 300 extend completely between the surfaces 130, 140. As illustrated by FIG. 3, however, it is not necessary for the carbon nanotubes 300 to extend that far. Although not shown, after the growth of the carbon nanotubes 300 has been terminated, the interstitial space remaining between the surfaces 130 and 140 can be filled with a matrix material such as a metal, plastic, or low vapor pressure oil like a silicone oil. Plastics or molten metals, like indium or a low melting point solder, can be introduced by injection or by capillary action, for example.

As noted above, the fairly narrow space between the surfaces 130, 140 imposes special requirements in order to maintain adequate growth conditions. One such requirement is the need to prevent carbon nanotubes 200 from growing in a ring in the space between the surfaces 130, 140. Should this occur, process gases are blocked from reaching the center of the space and, therefore, the growth of carbon nanotubes 200 near the center is greatly impeded. Accordingly, what is needed is a way to promote faster growth towards the center of the space compared to the edges. One way to achieve this goal is to tailor one or both of the catalyst layers 160, 170 to vary from edge to center by thickness, composition, distribution, or a combination thereof.

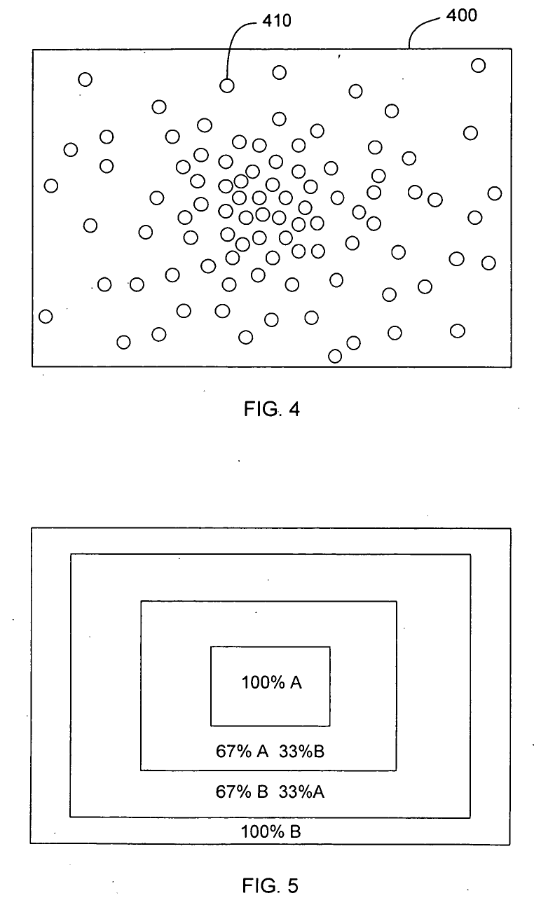

For example, FIG. 4 shows a top view of a surface of an object 400 having a catalyst layer comprising a plurality of catalyst sites 410. Carbon nanotubes can be made to grow preferentially from the catalyst sites 410. As the catalyst sites 410 are more densely populated near the center of the surface than towards the edges, carbon nanotubes will grow more densely towards the center. Fewer carbon nanotubes towards the edges will allow more process gases to reach into the center.

Another method for controlling the growth rate of the carbon nanotubes from the center to the periphery, so that the carbon nanotubes at the periphery do not impede the growth of those at the center, is to create a catalyst gradient in the catalyst layer. For instance, if two catalytic metals are known to catalyze the growth of carbon nanotubes at two different rates, the metal that promotes faster growth can be deposited preferentially towards the center while the metal that promotes slower growth can be deposited preferentially towards the periphery.

FIG. 5 shows a top view of a surface of an object 500 having a catalyst layer comprising a catalyst gradient between a catalyst A at the center of the surface and a catalyst B around the periphery of the surface. In this example catalyst A promotes faster carbon nanotube growth than catalyst B and the two catalysts are deposited in different concentrations in four concentric zones. Methods for producing two or more such concentric zones include co-deposition in conjunction with masking techniques. Additionally, instead of a step-wise gradient made by successive zones, a continuously variable gradient can also be produced, for example, through well known co-sputtering methods that employ moving shutters.

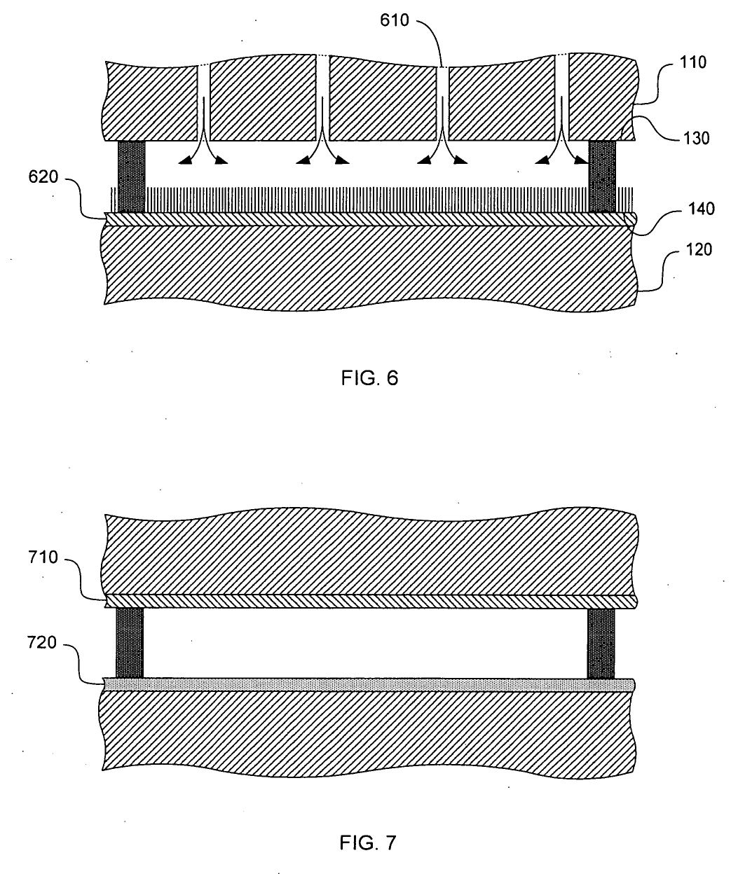

Still another technique for introducing process gases into the narrow space between the surfaces 130, 140 is through one or more vias 610 in one or both of the objects 110, 120 as illustrated in FIG. 6. In the embodiment shown in FIG. 6, carbon nanotubes 200 are only grown from the surface 140 opposite to the object 110 including the vias 610. However, it will be appreciated that carbon nanotubes 200 can be grown from either or both surfaces 130, 140 when process gases are introduced through vias 610. It will also be appreciated that the above-described gas delivery techniques can be used either alone or in various combinations.

As noted above with reference to FIG. 1, in some embodiments it is desirable to select different catalytic materials for the catalyst layers 160, 170 to induce carbon nanotubes with different properties to grow from the opposing surfaces 130, 140. For example, different catalyst materials can produce carbon nanotubes with different defect levels. Carbon nanotubes with low defect levels tend to be relatively straight, while those with higher levels of defects tend to curve and spiral. In this way the interdigitated carbon nanotubes can form a bond that is analogous to the bond formed by the hooks and loops of Velcro. FIG. 7 illustrates an exemplary embodiment in which catalyst layers 710 and 720 comprise different catalytic materials. It will be appreciated that using different catalytic materials for the layers 710 and 720 requires using catalytic materials that are both able to catalyze the same process gases to form carbon nanotubes, but with different properties, under the same temperature, flow rate, and pressure conditions.

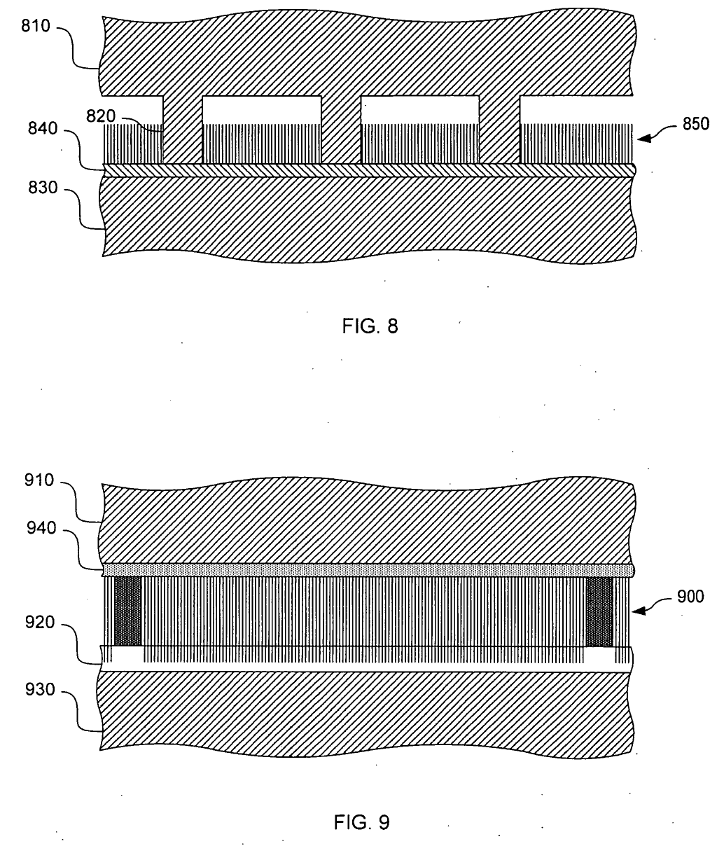

FIG. 8 illustrates still another exemplary embodiment of the invention in which an object 810 includes pedestals 820 that are integral with the object 810 and are used in place of the spacers 150 (FIG. 1). In some embodiments, the other object 830 includes a catalyst layer 840. As described above, carbon nanotubes 850 can be grown from the opposing surfaces, with or without the use of catalysts, and in some embodiments also from the surfaces of the pedestals 820, though not shown in FIG. 8.

FIG. 9 illustrates yet another exemplary embodiment of the invention. In this embodiment generally aligned carbon nanotubes 900 grow from a surface of one object 910 towards a metal layer 920 disposed on a surface of the other object 930. The carbon nanotubes 900 can grow, for example, from a catalyst layer 940 on object 910 and into the metal layer 920 to bond thereto. The metal layer 920 can comprise an element, alloy, or eutectic composition with a melting point near the reaction temperature at which the carbon nanotubes 900 are grown. Here, “a melting point near the reaction temperature” should be understood to include melting points that are below, at, and above the reaction temperature. Examples include aluminum, antimony, silver, strontium, and ytterbium which have melting points between about 600° C. and 1000° C.

In some embodiments the ends of the carbon nanotubes chemically react with the metal layer when the two come into contact. It will be understood that the carbon nanotubes can grow into the metal layer 920 until they reach the opposing surface, or stop short of the opposing surface, as shown in FIG. 9. Also, the choice of the metal for the metal layer 920 will be limited by certain considerations. For instance, the metal should be one that, under the particular growth conditions, does not poison carbon nanotube growth, nor promote the formation of undesirable carbon species such as graphite.

It will be understood that in the above described embodiments, in addition to varying the compositions of the catalyst layers 160, 170 (FIG. 1) across and between the layers, the process conditions for growing the carbon nanotubes can also be varied, for example, by raising or lowering the temperature during the growth phase. The composition, flow rate, and pressure of the process gases can also be altered while the carbon nanotubes are growing.

In the foregoing specification, the invention is described with reference to specific embodiments thereof, but those skilled in the art will recognize that the invention is not limited thereto. Various features and aspects of the above-described invention may be used individually or jointly. Further, the invention can be utilized in any number of environments and applications beyond those described herein without departing from the broader spirit and scope of the specification. The specification and drawings are, accordingly, to be regarded as illustrative rather than restrictive. It will be recognized that the terms “comprising,” “including,” and “having,” as used herein, are specifically intended to be read as open-ended terms of art.

1. A method for joining two objects comprising the steps of:
providing two objects having opposing surfaces kept apart by a distance; and
growing carbon nanotubes from a surface of one of the two objects until a mechanical bond is formed between the two objects.

2. The method of claim 1 wherein the surfaces are kept apart by a spacer.

3. The method of claim 1 wherein the spacer is a bead.

4. The method of claim 1 wherein one of the two objects includes a pedestal and the surfaces are kept apart by the pedestal.

5. The method of claim 1 wherein the two objects comprise a heat generation source and a thermal management aid.

6. The method of claim 1 wherein the step of growing the carbon nanotubes includes passing a process gas between the two opposing surfaces.

7. The method of claim 6 wherein the step of passing the process gas between the two opposing surfaces includes passing the process gas through a via in one object.

8. The method of claim 1 wherein one of the two opposing surfaces includes a catalyst layer, and the step of growing the carbon nanotubes includes growing the carbon nanotubes from the catalyst layer.

9. The method of claim 1 wherein the step of growing the carbon nanotubes includes growing the carbon nanotubes from both of the two opposing surfaces.

10. The method of claim 9 wherein the step of growing the carbon nanotubes from both of the two opposing surfaces includes interdigitating the carbon nanotubes from the two surfaces.

11. The method of claim 1 wherein the step of growing the carbon nanotubes includes growing generally aligned carbon nanotubes from one of the two opposing surfaces.

12. The method of claim 1 wherein the step of growing the carbon nanotubes includes growing carbon nanotubes with different properties from the opposing surfaces.

13. The method of claim 1 wherein the step of providing the two objects includes providing a clamping pressure to secure the two objects together while the carbon nanotubes are being grown.

14. The method of claim 1 further comprising the step of filling an interstitial space between the two objects with a matrix material after growing the carbon nanotubes.

15. The method of claim 1 further comprising the step of bonding the carbon nanotubes, growing from the surface of one of the two objects, to a metal layer disposed on a surface of the other of the two objects.

16. An interface between two objects having opposing surfaces separated by a distance, the interface comprising:
a first catalyst layer disposed on a first of the opposing surfaces and a second catalyst layer disposed on a second of the opposing surfaces; and
generally aligned carbon nanotubes extending from each of the catalyst layers towards the other.

17. The interface of claim 16 wherein the carbon nanotubes from the two surfaces are at least partially interdigitated.

18. The interface of claim 16 further comprising a spacer between the opposing surfaces.

19. The interface of claim 16 wherein the two objects comprise a heat generation source and a thermal management aid.

20. The interface of claim 16 wherein the carbon nanotubes extending from the opposing surfaces are characterized by different defect levels.

21. The interface of claim 16 wherein the first and second catalyst layers have different compositions.

22. The interface of claim 16 wherein one of the catalyst layers includes a compositional gradient.

23. The interface of claim 16 further comprising a matrix material disposed between the opposing surfaces and around the carbon nanotubes.

24. The interface of claim 16 further comprising carbon nanotubes extending essentially perpendicularly to the generally aligned carbon nanotubes extending from each of the catalyst layers, the carbon nanotubes together comprising a 3-dimensional mesh between the opposing surfaces.

25. The interface of claim 16 wherein the first catalyst layer includes a pattern so that the carbon nanotubes extend from the first catalyst layer according to the pattern.

26. An interface between two objects having opposing surfaces separated by a distance, the interface comprising:
a metal layer disposed on a first of the opposing surfaces and a catalyst layer disposed on a second of the opposing surfaces; and
generally aligned carbon nanotubes extending from the second of the opposing surfaces and bonded to the metal layer.

27. (canceled)

28. The interface of claim 26 wherein the metal of the metal layer has a melting point in the range of about 600° C. to about 1000° C.

29. An interface between two objects having opposing surfaces separated by a distance, the interface comprising:
a pedestal that is integral with a first of the two objects and extends across the distance to contact an opposing surface of a second of the two objects; and
generally aligned carbon nanotubes extending from the opposing surface of the second object towards an opposing surface of the first object.
